(19) United States
(12) Patent Application Publication
(10) Pub. No.: US 2016/0372409 A1
(43) Pub. Date: Dec. 22, 2016

(54) CIRCUIT BOARD STRUCTURE

(71) Applicant: KINSUS INTERCONNECT TECHNOLOGY CORP., Taoyuan (TW)

(72) Inventors: Jaen-Don Lan, New Taipei City (TW); PIN-CHUNG LIN, New Taipei City (TW); CHEN-RUI TSENG, Taoyuan City (TW); CHENG-EN HO, New Taipei City (TW); YU-AN CHEN, New Taipei City (TW)

(21) Appl. No.: 14/742,098

(22) Filed: Jun. 17, 2015

(51) Int. Cl. H01L 23/498

(52) U.S. Cl. CPC H01L 23/49822; H01L 23/49838; H01L 23/49866; H01L 23/49894

(57) ABSTRACT

Disclosed is a circuit board structure, including the first, second and third metal layers sequentially stacked on the substrate from bottom to top and formed by the sputtering process, the chemical plating process and the electroplating process, respectively. The substrate includes the stop layer and the resin layer stacked on the stop layer. The stop layer includes a pattern having at least one contact region, which is not covered by the resin layer. The first, second and third metal layers have an etched circuit pattern, respectively, and each of the etched circuit patterns is provided out of the corresponding contact region and aligned to each other to expose part of the resin layer. The etched circuit pattern is used for electrical connection. Since the first metal layer provides excellent surface properties, the second and third metal layers are well fixed and more stable.

### BACKGROUND OF THE INVENTION

1. Field of the Invention

The present invention generally relates to a circuit board structure, and more specifically to a circuit board structure having the first, second metal and third metal layers formed by the sputtering process, the chemical plating process and the electroplating process, respectively, stacked on the substrate such that the second and third metal layers are well fixed and more stable because the first metal layer provides excellent surface properties, and the etched circuit pattern of the third metal layer has a line width/pitch less than 10 μm to meet the requirements of fine line width/pitch by the application field of packaging electronic devices in consuming electronic products.

2. The Prior Arts

Recently, as the technology of the VLSI (very large scale integrated circuit) made great progress, the connection circuit has become much smaller. For example, in the 22 nm semiconductor technology, both chip density and ability of signal processing are increasingly enhanced. As a result, the line width/pitch of the connection circuit needs smaller size, and the current equipments and processes for mass production encounter tough challenge. Additionally, to further increase package density, the chips are usually stacked together and then processed by the three dimensional package. At this time, the line width/pitch of the circuit substrate needs to be reduced to 30-50 μm from 100 μm. As for the requirements by the current manufactures for increasingly reducing the line width/pitch, the surface structure of the copper layer for the circuit pattern should meet more strict requirements. Generally, roughness Rz of the copper layer in the printed circuit board (PCB) is 5-7 μm, and roughness Rz of the substrate is less than 5 μm. However, for the line width/pitch about 10-20 μm, roughness Rz of the copper layer should be about 2 μm, or otherwise the circuit pattern is easily distorted to cause the circuit board to fail to normal function. Sometimes, the circuit pattern is short circuited due to some remaining copper such that high precision and reliability for electrical connection can be implemented.

In the prior arts, the semi additive process (SAP) is usually used to manufacture the electrical circuit pattern with the line width/pitch less than 50 μm. For the line width/pitch less than 25 μm, The SAP needs to use ABF resin provided by Ajinomoto Fine-Techno Co., Inc. as the insulation material, or a PCF (primer coated copper foil) and a semi solid sheet (called Prepreg) provided by Mitsubishi Gas Chemical Company, INC., Ltd. for the pressing process. As for the PCF, one rough surface of the copper foil is first covered with a resin layer with a thickness of 2-3 μm and then processed by semi solidification, and the semi solid sheet and the copper foil are pressed together. The copper foil is removed and the surface of the resin layer has specific roughness. Thus, the chemical copper plating process (or called the electroless plating process) can form the chemical plated copper layer with strong adhesion on the rough surface of the resin layer, thereby manufacturing more precise circuit pattern.

As an example for SAP using the PCF, the specific implementation includes first pressing the PCF onto the inner circuit layer, removing the copper on the PCF to remain the resin with highly specific surface feature, and performing the chemical plating process to form the circuit pattern layer with fine line width/pitch.

However, one of the shortcomings for the above methods in the prior arts is that the remaining resin is not stable after the PCF is removed such that the circuit pattern layer formed by the chemical plating process is easy to break, peel off due to weak adhesion. It is thus difficult to prevent the portion of the circuit patter layer filling up the blind holes as connection plug with a vertical shape from being shifted or distorted. As a result, the electrical property and reliability of the electrical circuit of the circuit board are adversely affected.

Therefore, it is greatly needed to provide a new circuit board structure, which generally comprises the first, second metal and third metal layers sequentially stacked on the substrate from bottom to top and formed by the sputtering process, the chemical plating process and the electroplating process, respectively, such that the second and third metal layers are well fixed and more stable because the first metal layer provides excellent surface properties, and the etched circuit pattern of the third metal layer has a line width/pitch less than 10 μm to meet the requirements of fine line width/pitch by the application field of packaging electronic devices in consuming electronic products, thereby overcoming the above problems in the prior arts.

### SUMMARY OF THE INVENTION

The primary objective of the present invention is to provide a circuit board structure with fine line width/pitch to improve precision of the electrical circuit of the circuit board. The circuit board structure of the present invention comprises the substrate, the first metal layer, the second metal layer and the third metal layer. The substrate is formed of an electrical insulation material, and comprises a stop layer and a resin layer sequentially stacked on the substrate. The stop layer has a specific pattern comprising at least one contact region such that part of the substrate is not covered by the stop layer but covered by the resin layer. In other words, the resin layer covers the stop layer other than the contact region.

More specifically, the first, second and third metal layers are sequentially stacked on the stop layer and the resin layer from bottom to top. The first, second and third metal layers are formed by the sputtering process, the chemical plating process and the electroplating process, respectively. The portion of the first metal layer covering the contact region is a concave region, which is lower than other portion of the first metal layer. The first metal layer is provided with an etched circuit pattern out of the concave region, and each of the second and third metal layers also has a respective etched circuit pattern. The etched circuit patterns of the first, second and third metal layers are formed by the etching process and aligned to each other so as to expose part of the resin layer. The etched circuit pattern of the third metal layer is specifically used as an electrical circuit pattern for connection.

Moreover, the resin layer can be covered with a copper layer, which is processed by the pretreatment process such as the black process or the brown process, so as to oxidize the surface of the copper layer. The surface of the resin layer has roughness specified by Ra=0-1 μm and Rz=0-10 μm. The resin layer comprises a resin base material like epoxy resin, FR4, FR5, modified FR4 silicon, BT resin, polyphenylene oxide (PPO), polyimide (PI), Ajinomoto build-up film (ABF), polypropylene (PP) or photo imageable dielectric material (PIDM).

The substrate is embedded with an inner circuit layer, and the first metal layer may comprise the upper metal layer and the lower metal layer. The upper metal layer is stacked on the lower metal layer, and the lower metal layer is stacked on the exposed inner circuit layer. Preferably, the upper metal layer comprises copper (Cu), the lower metal layer comprises titanium (Ti), chromium (Cr) or tantalum (Ta), and the second and third metal layers comprise copper.

The above first metal layer may further comprise the bottom metal layer, which is provided under the lower metal layer and in contact with the exposed inner circuit layer. The bottom metal layer comprises titanium nitride (TiN). The resin layer further comprises a reinforcing material uniformly dispersed in the resin base material, and the reinforcing material comprises glass fiber or carbon fiber.

Since the adhesion between the adjacent first, second and third metal layers is strongly enhanced, it is difficult to peel off each other. Especially, the first metal layer formed by the sputtering process is in contact with the contact region and the resin layer to greatly strengthen adhesion such that the circuit board structure of the present invention is well fixed and stable without risk of distorting or warping, thereby providing high reliability and endurance.

Specifically, the circuit board structure of the present invention provides fine line width/pitch less than 10 μm so as to greatly improve electrical quality. Particularly, the circuit board structure is simple in design and easy to manufacture so as to greatly reduce the cost and meet the requirements of fine line width/pitch by the application field of packaging electronic devices in consuming electronic products.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a view showing a circuit board structure according to the first embodiment of the present invention; and

FIG. 2 is a view showing a circuit board structure according to the second embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

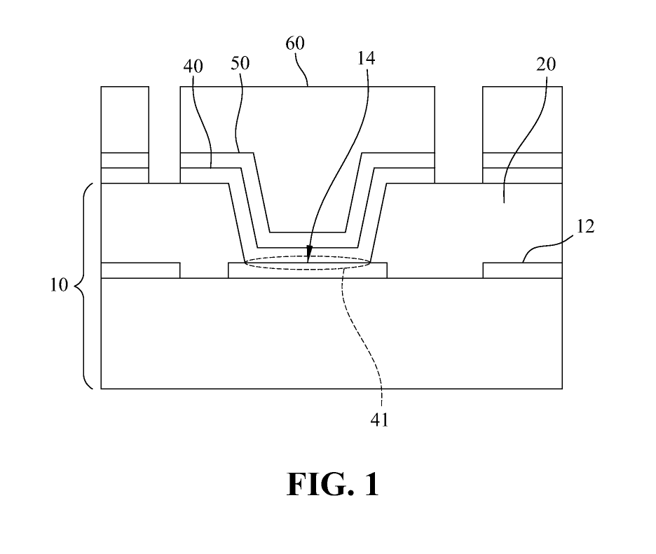

Please refer to FIG. 1 illustrating the circuit board structure according to the first embodiment of the present invention. As shown in FIG. 1, the circuit board structure of the first embodiment generally comprises the substrate 10, the first metal layer 40, the second metal layer 50 and the third metal layer 60 for providing fine line width/pitch. Substantially, the substrate 10 is formed of an electrical insulation material, and comprises a stop layer 12 and a resin layer 20 sequentially stacked on the substrate 10. The stop layer 12 has a specific pattern, which comprises at least one contact region 14. It should be noted that only one contact region 14 is shown for clearly describing the aspects of the present invention, but not intended to limit the scope of the present invention. It is obvious that part of the substrate 10 is not covered by the stop layer 12 but covered by the resin layer 20. In other words, the resin layer 20 covers the stop layer 12 other than the contact region 14.

Furthermore, the first metal layer 40, the second metal layer 50 and the third metal layer 60 are stacked from bottom to top on the resin layer 20 and the contact region 14 of the stop layer 12. The portion of the first metal layer 40 covering the contact region is a concave region 41, as shown by the dashed line in FIG. 1. In other words, the concave region 41 is lower than other portion of the first metal layer 40.

In addition, the first metal layer 40 is provided with an etched circuit pattern out of the concave region 41, and each of the second metal layer 50 and the third metal layer 60 also has a respective etched circuit pattern. In particular, the etched circuit patterns of the first metal layer 40, the second metal layer 50 and the third metal layer 60 are formed by the traditional etching process and aligned to each other so as to expose part of the resin layer 20.

More specifically, the above first metal layer 40, the second metal layer 50 and the third metal layer 60 are formed by the sputtering process, the chemical plating process (or the electroless plating process) and the electroplating process, respectively. The strength of adhesion between the above first metal layer 40, the second metal layer 50 and the third metal layer 60 is greatly enhanced, and it is thus difficult to peel off each other. In particular, the first metal layer 40 formed by the sputtering process is in contact with the contact region 14 and the resin layer 20 to greatly strengthen adhesion such that the circuit board structure of the present invention is well fixed and stable without risk of distorting or warping, thereby providing high reliability and endurance.

Moreover, the resin layer 20 can be covered with a copper layer (not shown), which is processed by the pretreatment process such as the black process or the brown process used to oxidize the surface of the copper layer.

Preferably, the resin layer 20 comprises a resin base material like epoxy resin, FR4, FR5, modified FR4 silicon, BT resin, polyphenylene oxide (PPO), polyimide (PI), Ajinomoto build-up film (ABF), polypropylene (PP) or photo imageable dielectric material (PIDM), and the surface of the resin layer 20 has roughness specified by Ra=0-1 μm and Rz=0-10 μm.

In addition, the upper and lower surfaces of the substrate 10 are embedded with an inner circuit layer, respectively, and the first metal layer 40 may comprise the upper metal layer and the lower metal layer (not shown), wherein the upper metal layer is stacked on the lower metal layer, and the lower metal layer is stacked on the exposed inner circuit layer. It is preferred that the upper metal layer comprises copper (Cu), the lower metal layer comprises titanium (Ti), chromium (Cr) or tantalum (Ta), and the second and third metal layers comprise copper.

The first metal layer 40 may further comprise the bottom metal layer (not shown), which is provided under the lower metal layer and in contact with the exposed inner circuit layer. The bottom metal layer comprises titanium nitride (TiN).

To further enhance the mechanical strength of the circuit board structure to avoid warping or distorting, the resin layer 20 further comprises a reinforcing material uniformly dispersed in the resin base material, and the reinforcing material comprises glass fiber or carbon fiber so as to form a composite material.

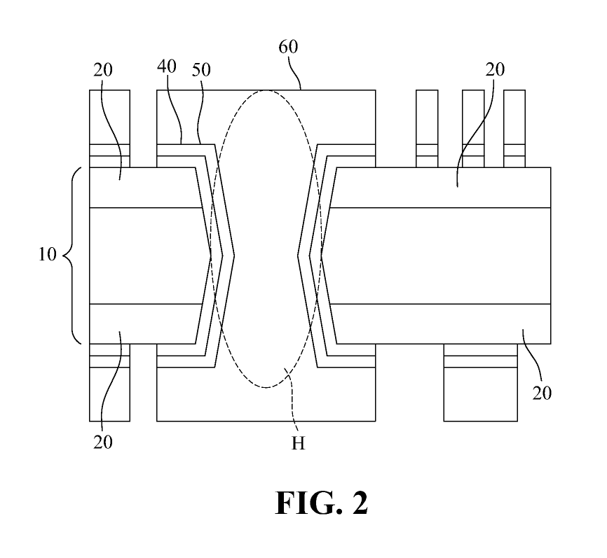

Please refer to FIG. 2 illustrating the circuit board structure according to the second embodiment of the present invention. As shown in FIG. 2, the circuit board structure of the second embodiment is similar to the circuit board structure of the first embodiment, and comprises the substrate 10, the first metal layer 40, the second metal layer 50 and the third metal layer 60 for providing fine line width/pitch. Since the aspects of the materials forming the substrate 10, the first metal layer 40, the second metal layer 50 and the third metal layer 60 are the same as those of the first embodiment, the related description is thus omitted hereinafter.

It should be noted that one difference between the first and second embodiments is that the substrate 10 of the second embodiment does not comprise the stop layer 12 of the first embodiment, the resin layer 20 of the second embodiment is provided on the upper and lower surface of the substrate 10, and the first metal layer 40, the second metal layer 50 and the third metal layer 60 are sequentially stacked on the resin layer 20. Another difference is that the substrate 10 has at least one conduction hole H, which is substantially a through-hole penetrating the upper and lower surfaces of the substrate 10. Therefore, the first metal layer 40 and the second metal layer 50 sequentially cover the sidewall of the conduction hole H, and the third metal layer 60 fills up the conduction hole H. In other words, the third metal layer 60 forms a plug in the conduction hole H.

Similar to the first embodiment, the second embodiment provides the first metal layer 40, the second metal layer 50 and the third metal layer 60 with the etched circuit patterns, respectively, which are out of the conduction hole H and aligned to each other. Thus, part of the resin layer 20 is exposed. The etched circuit pattern of the third metal layer is used as an electrical circuit for connection, thereby achieving the function of the circuit board. Further, the etched circuit patterns of the first metal layer 40, the second metal layer 50 and the third metal layer 60 are implemented by the circuit etching process.

The upper surface of the resin layer 20 can be covered with a copper layer (not shown), which is processed by the pretreatment process including the black process or the brown process to oxidize the surface of the copper layer.

Additionally, the upper and lower surfaces of the substrate 10 are embedded with an inner circuit layer (not shown), respectively. The first metal layer 40 may comprise the upper, lower metal layers (not shown), and the bottom metal layer (not shown) similar to the first embodiment, and the related description is thus omitted hereinafter.

The resin layer 20 may comprise a reinforcing material well dispersed in the resin base material to increase the mechanical strength and warping resistance. The reinforcing material comprises glass fiber or carbon fiber.

From the above mention, one primary feature of the present invention is that the first metal layer formed by the sputtering process, the second metal layer formed by the chemical plating process and the third metal layer formed by the electroplating process are sequentially stacked on the resin layer of the substrate such that the second and third metal layers are more stable and well fixed due to the excellent surface properties provided by the first metal layer. Thus, the line width/pitch of the electrical circuit of the circuit board can be reduced to less than 10 μm, thereby meeting the requirements of fine line width/pitch by the application field of packaging electronic devices in consuming electronic products.

In particular, the first metal layer comprises the upper metal layer formed of copper or aluminum, which is easily oxidized, and further comprises the lower metal layer formed of titanium, chromium or tantalum, which is used to increase activity so as to help the subsequent processes. In addition, the first metal layer may further comprise the bottom metal layer formed of titanium nitride, which is provided under the lower metal layer to contact the inner metal layer, such that the mechanical strength of the first metal and the cohesion between the inner metal layer and the first metal layer are greatly increased. Therefore, the circuit board structure of the present invention indeed has high stability and reliability, thereby overcoming the problems in the prior arts.

Although the present invention has been described with reference to the preferred embodiments thereof, it is apparent to those skilled in the art that a variety of modifications and changes may be made without departing from the scope of the present invention which is intended to be defined by the appended claims.

1. A circuit board structure, comprising:
a substrate formed of an electrical insulation material and comprising a stop layer and a resin layer, the stop layer having a pattern, the pattern having at least one contact region, part of the substrate not covered by the stop layer but covered by the resin layer, a portion of the stop layer other than the at least one contact region covered by the resin layer;
a first metal layer covering the resin layer, a portion of the first metal layer covering the contact region being a concave region and lower than other portion of the first metal layer, the first metal layer provided with an etched circuit pattern out of the concave region;
a second metal layer immediately covering the first metal layer and comprising an etched circuit pattern; and
a third metal layer immediately covering the second metal layer and comprising an etched circuit pattern,
wherein the resin layer, the first metal layer and the second metal layer form a recessed area above the second metal layer over the concave region of the first metal layer, the etched circuit patterns of the first, second and third metal layers are aligned to each other so as to expose part of the resin layer, and the recessed area is filled with the third metal layer so that the third metal layer has a flat upper surface between the exposed part of the resin laver.

2. The circuit board structure as claimed in claim 1, wherein the first metal layer is formed through a sputtering process, the second metal layer is formed through a chemical plating process or an electroless plating process, and the third metal layer is formed through an electroplating process.

3. The circuit board structure as claimed in claim 1, wherein the etched circuit patterns of the first, second and third metal layers are formed by a circuit etching process.

4. The circuit board structure as claimed in claim 1, wherein an upper surface of the resin layer is covered with a copper layer, and the copper layer is treated by a pretreatment process comprising a black process or a brown process for oxidizing a surface of the copper layer.

5. The circuit board structure as claimed in claim 1, wherein the resin layer is formed of a resin base material comprising epoxy resin, FR4, FR5, modified FR4 silicon, BT resin, polyphenylene oxide (PPO), polyimide (PI), Ajinomoto build-up film (ABF), polypropylene (PP) or photo imageable dielectric material (PIDM), and the upper surface of the resin layer has a roughness specified by Ra=0-1 μm and Rz=0-10 μm.

6. The circuit board structure as claimed in claim 1, wherein an upper surface and/or a lower surface of the substrate is embedded with an inner circuit layer.

7. The circuit board structure as claimed in claim 6, wherein the first metal layer comprises an upper metal layer and a lower metal layer, the upper metal layer is stacked on the lower metal layer, the lower metal layer is stacked on the exposed inner circuit layer, the upper metal layer comprises copper (Cu), the lower metal layer comprises titanium (Ti), chromium (Cr) or tantalum (Ta), and the second and third metal layers comprise copper.

8. The circuit board structure as claimed in claim 7, wherein the first metal layer further comprises a bottom metal layer provided under the lower metal layer and being in contact with the exposed inner circuit layer, and the bottom metal layer comprises titanium nitride (TiN).

9. The circuit board structure as claimed in claim 5, wherein the resin layer further comprises a reinforcing material uniformly dispersed in the resin base material, and the reinforcing material comprises glass fiber or carbon fiber.

10-19. (canceled)
